(19) United States
(12) Patent Application Publication
(10) Pub. No.: US 2016/0073549 A1
(43) Pub. Date: Mar. 10, 2016

(54) CLIP FOR CLAMPING ELECTRONIC COMPONENT

(71) Applicant: DELTA ELECTRONICS, INC., Taoyuan County (TW)

(72) Inventors: Hsi-An LIU, Taoyuan County (TW); Hung-Chang HSIEH, Taoyuan County (TW); Shih-Ming YAN, Taoyuan County (TW)

(21) Appl. No.: 14/587,854

(22) Filed: Dec. 31, 2014

(30) Foreign Application Priority Data
Sep. 5, 2014 (TW) 103130699

(51) Int. Cl. H05K 7/20; F16B 2/24

(52) U.S. Cl. CPC H05K 7/2039; F16B 2/245

(57) ABSTRACT

A clip for clamping an electronic device includes a main body and a plurality of claws. Each claw extends outwardly from an edge of the main body, and each claw has a clamping portion formed on the claw for abutting and connecting the electronic device, and clamping portions are arranged on at least two different planes, so that different claws produce appropriate clamping forces at different clamping positions respectively.

### FIELD OF THE INVENTION

The present invention relates to a clip for clamping an electronic device, and more particularly the clip having a plurality of claws.

### BACKGROUND OF THE INVENTION

Power transistor is one of the transistors generally generating high heat during its high-current operation, so that it is necessary to attach a heat sink onto the power transistor to eliminate the heat generated by the power transistor. To conduct the heat from the power transistor to the heat sink effectively, the heat sink and the power transistor must be clamped to maintain a close contact to reduce the gap between the heat sink and the power transistor, so as to achieve a good thermal conduction.

At present, a transistor clip is commonly used as the clamping mechanism, and there are two main types of transistor clips, respectively: a transistor clip having a heat sink attached onto a transistor clip and a claw extended from the transistor clip for pressing the power transistor at the heat sink, and a U-shaped transistor clip having two opposite claws for clamping the power transistor and the heat sink between the two claws.

Most of the conventional power transistors are not components with the same thickness, so that the surface of the power transistor has a plurality of discontinuous planes with a height difference between the planes, and the claws just can touch the plane of a greater thickness only. Most transistor clips are made by bending a metal plate, and the power transistor is operated when a high current is passed through its pins, so that if the clamping point of the transistor clip is too close to the pins of the power transistor, a short circuit will occur easily.

Based on the aforementioned limitation, the conventional transistor clip must be far away from the pins, and the transistor clip is unable to clamp a surface of the transistor at a position of a lower height. Therefore, the area available for the conventional transistor clip to clamp the surface of the transistor is very small, and a sufficient clamping force cannot be provided. As a result, the transistor clip may become elastically fatigue and fall off easily after holding the transistor or using the clip for a long time.

In addition, the size of the power transistor at a smaller thickness has a relatively smaller tolerance and the power transistor is capable of bearing a relatively greater pressure and has a better clamping point with respect to the position with a greater thickness. However, the conventional transistor clip fails to clamp at a better clamping point due to the aforementioned limitation.

In view of the aforementioned problems of the prior art, the inventor of the present invention based on years of experience in the related industry to conduct extensive researches and experiments and provide a feasible solution in accordance with the present invention to overcome the problems of the prior art.

### SUMMARY OF THE INVENTION

Therefore, it is a primary objective of an exemplary embodiment of the present application to overcome the problems of the prior art by providing a transistor clip with a plurality of claws.

To achieve the aforementioned objective, the present invention provides a clip for clamping an electronic device, and the clip comprises a main body and a plurality of claws. Each claw is extended outwardly from an edge of the main body, and each claw has a clamping portion formed thereon for abutting and coupling the electronic device, and the clamping portions are arranged on at least two different planes respectively.

Preferably, the end of each claw is bent to form the clamping portion. Each claw has an elastic arm formed and coupled between the main body and the clamping portion, and the claw is bent into a substantially L-shape, and the clip is bendable at a position where the elastic arm and the main body are coupled. The main body has a positioning pin extended outwardly from the main body and bent into a position substantially perpendicular to the main body, and the positioning pin and the claw are coupled to two opposite sides of the main body respectively, and the main body has a through hole formed thereon.

To achieve the aforementioned objective, the present invention further provides a clip for clamping an electronic device, comprising: a main body, a plurality of claws and a clamping board. Each claw is extended outwardly from an edge of the main body, and each claw has a clamping portion formed thereon for abutting and coupling the electronic device, and the clamping portions are arranged on at least two different planes respectively. The clamping board is extended outwardly from the other edge of the main body and configured corresponsive to the claws, and the clip is bendable at a connecting position of the clamping board and the main body.

Preferably, the end of each claw is bent to form the clamping portion. Each claw has an elastic arm formed and coupled between the main body and the clamping portion, wherein the elastic arm is bent into a substantially L-shape and the clip is bendable at a connecting position of the elastic arm and the main body.

To achieve the aforementioned objective, the present invention further provides a clip for clamping an electronic device, comprising a plurality of main bodies and a plurality of claws, and each claw has a clamping portion formed thereon for abutting and coupling the electronic device, and the clamping portions are arranged on at least two different planes respectively. Both ends of each claw are coupled to each main body.

Preferably, an elastic arm is formed separately at both ends of each claw, and the claw is bent to form the clamping portion disposed between two elastic arms, and each main body has a through hole formed thereon. The main body has a positioning pin extended therefrom and bent into a position substantially perpendicular to the main body, and the positioning pin and the claws are coupled to two opposite sides of the main body respectively. The clip for clamping an electronic device in accordance with the present invention comprises a plurality of claws, so that different claws are provided for clamping the corresponding clamping sides of the electronic device respectively, and an appropriate clamping force may be applied to each clamping side to assure that the electronic device is clamped tightly onto the heat sink.

### BRIEF DESCRIPTION OF THE DRAWINGS

FIG. 1 is a perspective view of a clip for clamping an electronic device in accordance with a first preferred embodiment of the present invention;

FIG. 2 is schematic view of a clip for clamping an electronic device in accordance with the first preferred embodiment of the present invention;

FIG. 3 is a schematic view of a clip for clamping an electronic device in accordance with the first preferred embodiment of the present invention;

FIG. 4 is a schematic view of a clip for clamping an electronic device in accordance with a second preferred embodiment of the present invention;

FIG. 5 is another schematic view of a clip for clamping an electronic device in accordance with the second preferred embodiment of the present invention;

FIG. 6 is a schematic view of a clip for clamping an electronic device in accordance with a third preferred embodiment of the present invention; and

FIG. 7 is another schematic view of a clip for clamping an electronic device in accordance with the third preferred embodiment of the present invention

### DESCRIPTION OF THE PREFERRED EMBODIMENTS

The technical contents of the present invention will become apparent with the detailed description of a preferred embodiment accompanied with the illustration of related drawings as follows. It is noteworthy that same numerals are used for representing same respective elements in the drawings.

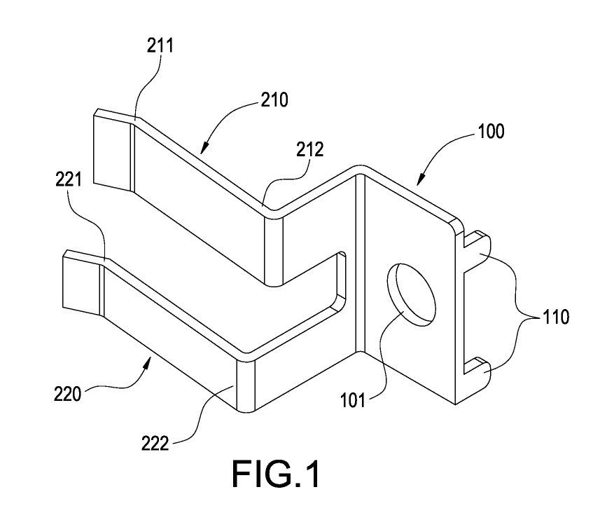

With reference to FIGS. 1 to 3 for a clip for clamping an electronic device in accordance with the first preferred embodiment of the present invention, the clip for clamping an electronic device is provided for clamping and attaching an electronic device 10 on a heat sink 20, and the clip comprises a main body 100 and a plurality of claws 210, 220.

In this preferred embodiment, the main body 100 is preferably a rectangular metal plate having a through hole 101 formed thereon, and a plurality of positioning pins 110 extended outwardly from an edge of the main body 100, and each positioning pin 110 is bent to a position substantially perpendicular to the main body 100.

In this preferred embodiment, two claws 210, 220 are extended outwardly from the other edge of the main body 100 and configured corresponsive to the positioning pins 110 respectively. However, the quantity of claws 210, 220 of the present invention is not limited. Each claw 210, 220 is a bent long-strip metal plate, and the two claws 210, 220 are parallel to each other. An end of each claw 210, 220 is bent to form a clamping portion 211, 221, and the clamping portion 211, 221 is provided for abutting at the electronic device 10, wherein the two clamping portions 211, 221 of this preferred embodiment are arranged on different planes respectively. Each claw 210, 220 has an elastic arm 212, 222 formed and coupled between the main body 100 and the clamping portion 211, 221. In this preferred embodiment, the elastic arm 212, 222 is bent into a substantially L-shape, and the bending angle of the elastic arm 212, 222 is preferably an acute angle, and the elastic arm 212, 222 and the main body 100 are configured to be perpendicular to each other at the connecting position of the elastic arm 212, 222 and the main body 100.

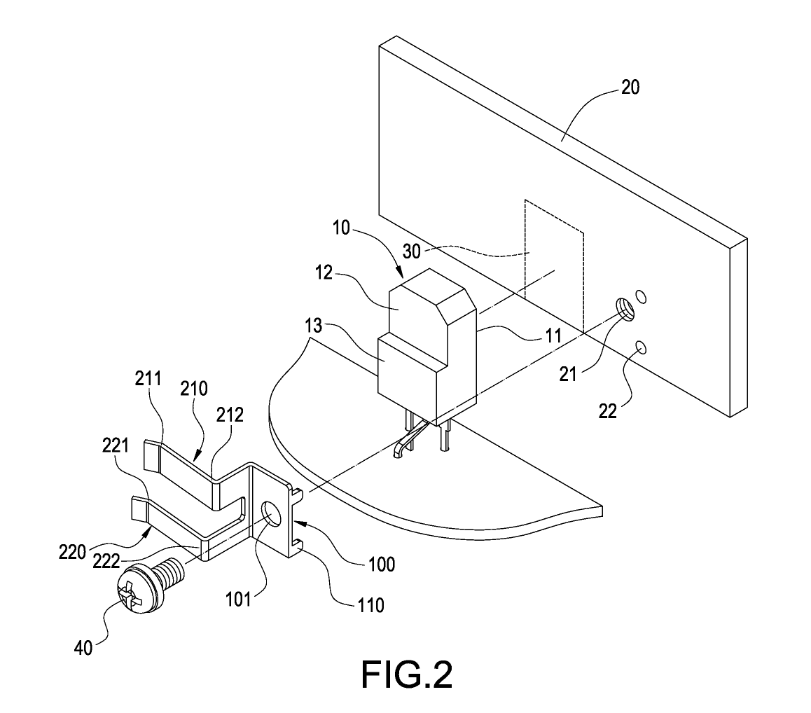

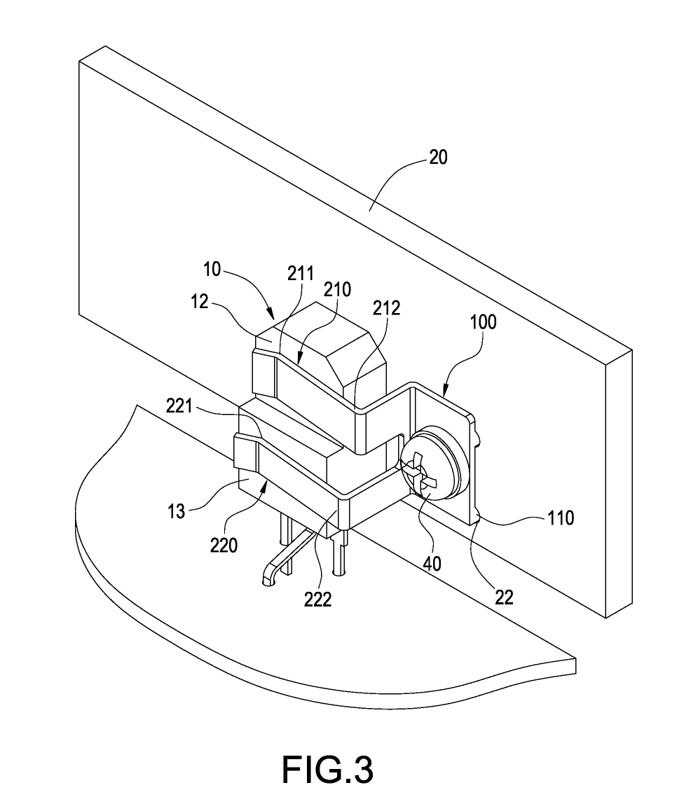

With reference to FIGS. 2 and 3 for this preferred embodiment of the present invention, the electronic device 10 includes but not limited to a power transistor, and the clip for clamping the electronic device is provided for clamping and attaching the electronic device 10 onto the heat sink 20, wherein the heat sink 20 has a screw hole 21 formed thereon and a plurality of positioning holes 22 corresponding to the positioning pins 110 respectively, and the electronic device 10 has a heat dissipating surface 11 and a plurality of clamping sides 12, 13 (preferably including but not limited to two clamping sides 12, 13 in this preferred embodiment) disposed opposite to the heat dissipating surface 11, and there is a height difference between the clamping sides 12, 13, so that the clamping sides 12, 13 are not connected to each other.

In this preferred embodiment, a screw 40 is passed through the through hole 101 of the main body 100 and screwed to the screw hole 21 of the heat sink 20, such that the clip is mounted and secured onto the heat sink 20. In addition, each positioning pin 110 of the clip is inserted into the corresponding positioning hole 22 of the heat sink 20 to fix the clip and prevent the rotation of the clip.

The electronic device 10 is installed between each claw 210, 220 and the heat sink 20, and the clamping portion 211, 221 of each claw 210, 220 presses at the corresponding clamping side 12, 13 of the electronic device 10, so that a clamping force produced by each elastic arm 212, 222 clamps the electronic device 10 and attaches the heat dissipating surface 11 of the electronic device 10 onto the heat sink 20. Preferably, the heat dissipating surface 11 and the heat sink 20 may clamp a thermal conducting structure 30 to improve the thermal conduction between the heat dissipating surface 11 and the heat sink 20. The thermal conducting structure 30 preferably includes (but not limited to) a thermally conductive glue or a thermally conductive pad.

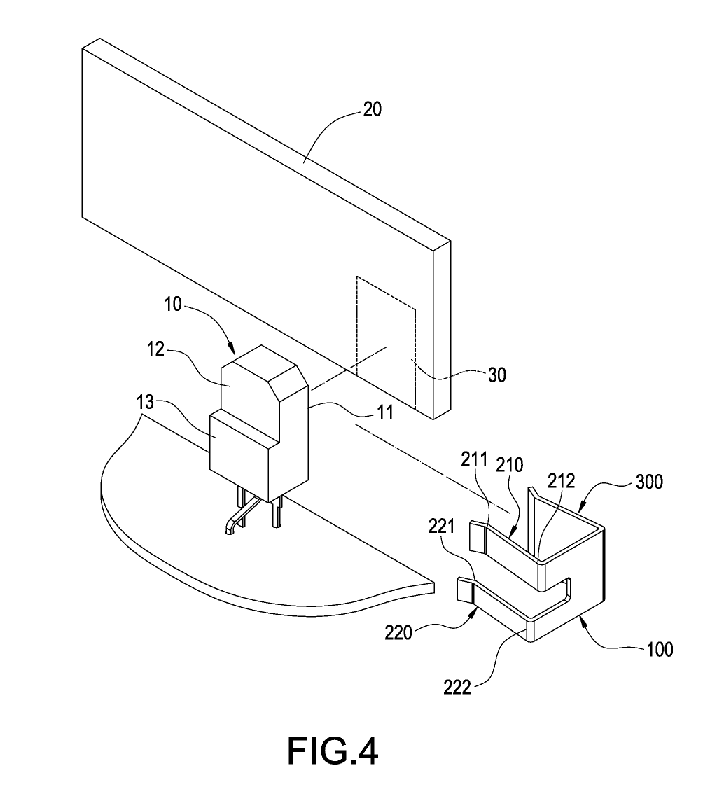

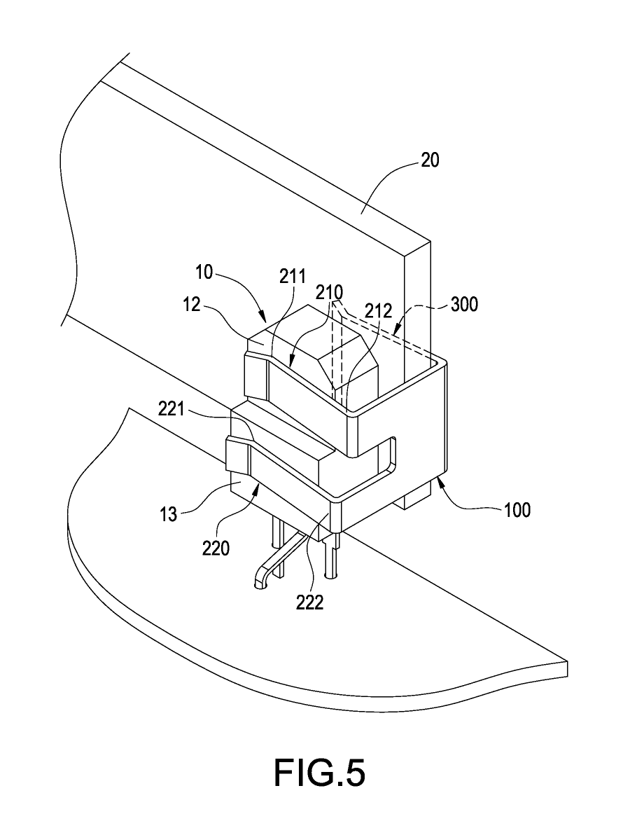

With reference to FIGS. 4 and 5 for a clip for clamping an electronic device in accordance with the second preferred embodiment of the present invention, the clip comprises a main body 100, a plurality of claws 210, 220 and a clamping board 300.

In this preferred embodiment, the main body 100 is preferably a rectangular metal plate, and two claws 210, 220 are extended outwardly from an edge of the main body 100, wherein the quantity of claws 210, 220 of the present invention is not limited. Each claw 210, 220 is a bent long-strip metal plate, and two claws 210, 220 are parallel to each other. An end of each claw 210, 220 is bent to form a clamping portion 211, 221 and the clamping portion 211, 221 is provided for pressing at the electronic device 10, wherein the two clamping portions 211, 221 of this preferred embodiment are arranged on different planes respectively. Each claw 210, 220 has an elastic arm 212, 222 formed and coupled between the main body 100 and the clamping portion 211, 221. In this preferred embodiment, the elastic arm 212, 222 is bent into an L-shape and the bending angle is preferably an acute angle, and the elastic arm 212, 222 and the main body 100 are bent at a connecting position and substantially perpendicular to each other.

A clamping board 300 is extended outwardly from the other edge of the main body 100 and disposed opposite to the claws 210, 220, and the clamping board 300 and the main body 100 are bent into an L-shaped at a connecting position, and the bending angle is preferably an acute angle.

The clip for clamping an electronic device in accordance with the present invention is provided for clamping and attaching the electronic device 10 onto the heat sink 20. In this preferred embodiment, the electronic device 10 includes, but not limited to, a power transistor. The electronic device 10 has a heat dissipating surface 11 formed thereon and a plurality of clamping sides 12, 13 (including, but not limited to, two clamping sides 12, 13 in this preferred embodiment) disposed opposite to the heat dissipating surface 11, and there is a height difference between the clamping sides 12, 13, so that the clamping sides 12, 13 are not coupled to each other.

In this preferred embodiment, the heat dissipating surface 11 of the electronic device 10 is attached onto the heat sink 20, and the electronic device 10 and the heat sink 20 are clamped between each claw 210, 220 and the clamping board 300, and the clamping portion 211, 221 of each claw 210, 220 presses at the corresponding clamping side 12, 13 of the electronic device 10, and each elastic arm 212, 222 produces a clamping force to clamp the electronic device 10 and attaches the heat dissipating surface 11 to the heat sink 20 tightly. Preferably, the heat dissipating surface 11 and the heat sink 20 may include a thermal conducting structure 30 for improving the thermal conduction between the heat dissipating surface 11 and the heat sink 20. The thermal conducting structure 30 preferably includes (but not limited to) a thermally conductive glue and a thermally conductive pad.

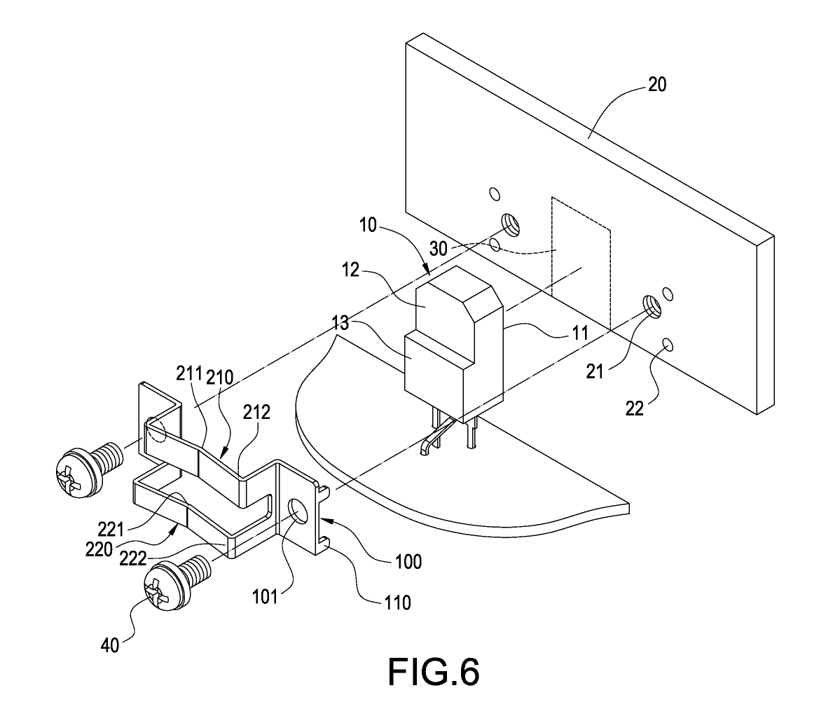

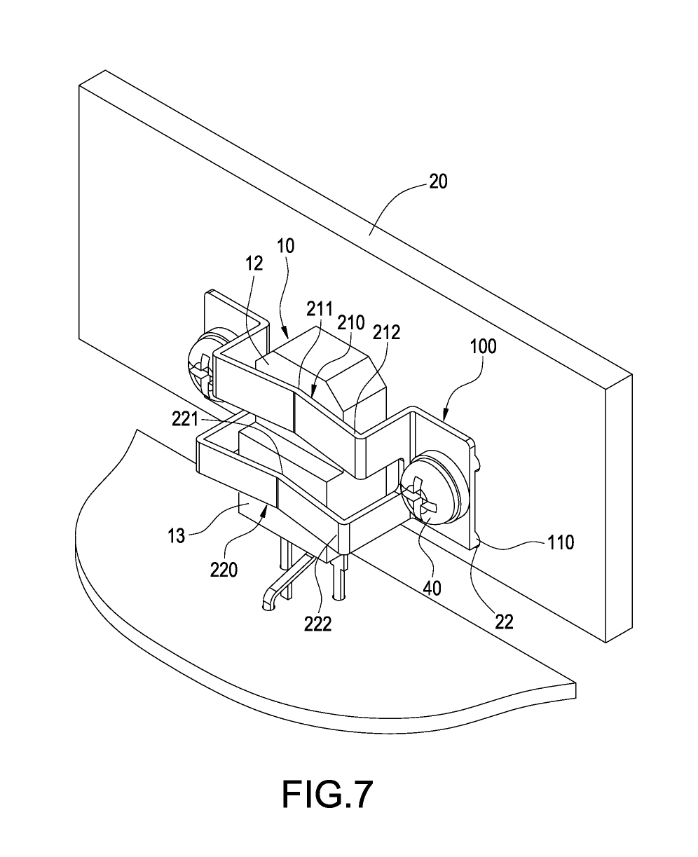

With reference to FIGS. 6 and 7 for a clip for clamping an electronic device in accordance with the third preferred embodiment of the present invention, the clip comprises a plurality of main bodies 100 and a plurality of claws 210, 220.

In this preferred embodiment of the present invention, the clip for clamping an electronic device preferably comprises, but not limited to, two main bodies 100, and each main body 100 is preferably a rectangular metal plate and the main body 100 has a through hole 101 formed thereon, and each main body 100 preferably has a plurality of positioning pins 110 extended outwardly from an edge of each main body 100, and each positioning pin 110 is bent to a position substantially perpendicular to the main body 100.

In this preferred embodiment of the present invention, the clip for clamping an electronic device preferably comprises, but not limited to, two claws 210, 220. Each claw 210, 220 is a bent long-strip metal plate, and the two claws 210, 220 are parallel to each other. Both ends of each claw 210, 220 separately have an elastic arm 212, 222, and each elastic arm 212, 222 is coupled to each main body 100, and the middle section of each claw 210, 220 is bent to form a clamping portion 211, 221 disposed between two elastic arms 212, 222, and the clamping portion 211, 221 is provided for pressing at the electronic device 10. In this preferred embodiment, the two clamping portions 211, 221 are arranged on different planes respectively.

In this preferred embodiment, the connecting position of each main body 100 and claw 210, 220 is preferably disposed on the same edge of the main body 100. Each elastic arm 212, 222 is bent into an L-shape, and the bending angle is preferably an acute angle, and the elastic arm 212, 222 and the main body 100 are bent at the connecting position and configured to be substantially perpendicular to each other.

In the present invention, the clip for clamping an electronic device is provided for clamping and attaching the electronic device 10 onto the heat sink 20. In this preferred embodiment, the electronic device 10 includes, but not limited to, a power transistor. The heat sink 20 has two screw holes 21 corresponsive to the through holes 101 respectively, and a plurality of positioning holes 22 corresponsive to the positioning pins 110 respectively, and the electronic device 10 has a heat dissipating surface 11 formed thereon and a plurality of clamping sides 12, 13 (preferably including but not limited to two clamping sides 12, 13 in this preferred embodiment) disposed opposite to the heat dissipating surface 11, and there is a height difference between the clamping sides 12, 13, so that the clamping sides 12, 13 are not connected to each other.

In this preferred embodiment, a screw 40 is passed through the through hole 101 of each main body 100 and screwed into the corresponding screw hole 21 of the heat sink 20 to mount and secure the clip onto the heat sink 20. In addition, each positioning pin 110 of the clip is inserted into the corresponding positioning hole 22 of the heat sink 20 to fix the clip and prevent the clip from sliding.

The electronic device 10 is installed between each claw 210, 220 and the heat sink 20, and the clamping portion 211, 221 of each claw 210, 220 presses at the corresponding clamping side 12, 13 of the electronic device 10, and a clamping force produced by each elastic arm 212, 222 clamps the electronic device 10 and attaches the heat dissipating surface 11 of the electronic device 10 to the heat sink 20 tightly. Preferably, the heat dissipating surface 11 and the heat sink 20 may include a thermal conducting structure 30 for improving the thermal conduction between the heat dissipating surface 11 and the heat sink 20. The thermal conducting structure 30 preferably includes (but not limited to) a thermally conductive glue and a thermally conductive pad.

The clip for clamping an electronic device in accordance with the present invention comprises a plurality of claws 210, 220, and different claws 210, 220 clamp the corresponding clamping sides 12, 13 of the electronic device 10, so that a design with adjusting elastic arms allows users to apply an appropriate clamping force on each clamping side 12, 13 and clamp the clamping side 12 of the electronic device 10 at a position with a smaller thickness, so as to assure the electronic device 10 to be fixed and clamped onto the heat sink 20 tightly.

While the invention has been described by means of specific embodiments, numerous modifications and variations could be made thereto by those skilled in the art without departing from the scope and spirit of the invention set forth in the claims.

What is claimed is:

1. A clip for clamping an electronic device, comprising:
a main body; and
a plurality of claws, each being extended from an edge of the main body, and having a clamping portion for abutting and coupling the electronic device, and the clamping portions being arranged on at least two different planes respectively.

2. The clip for clamping an electronic device according to claim 1, wherein the main body has a positioning pin extended from the main body, and the positioning pin is bent to a position substantially perpendicular to the main body.

3. The clip for clamping an electronic device according to claim 2, wherein the positioning pin and the claws are coupled to two opposite sides of the main body respectively.

4. The clip for clamping an electronic device according to claim 1, wherein each of the claws has an end being bent to form the clamping portion.

5. The clip for clamping an electronic device according to claim 4, wherein each of the claws has an elastic arm formed and coupled between the main body and the clamping portion.

6. The clip for clamping an electronic device according to claim 5, wherein the clip is bendable at a connecting position of the elastic arm and the main body.

7. The clip for clamping an electronic device according to claim 5, wherein the elastic arm is bent into a substantially L-shape.

8. The clip for clamping an electronic device according to claim 7, wherein the main body has a through hole formed thereon.

9. A clip for clamping an electronic device, comprising:
a main body;
a plurality of claws, each being extended outwardly from an edge of the main body, and having a clamping portion for abutting and coupling the electronic device, and the clamping portions being arranged on at least two different planes respectively; and
a clamping board, extended from the other edge of the main body, and configured to be corresponsive to the claws.

10. The clip for clamping an electronic device according to claim 9, wherein the clip is bendable at a connecting position of the clamping board and the main body.

11. The clip for clamping an electronic device according to claim 9, wherein each of the claws has an end being bent to form the clamping portion.

12. The clip for clamping an electronic device according to claim 11, wherein the claws are bent towards the clamping board to form the clamping portion.

13. The clip for clamping an electronic device according to claim 11, wherein each of the claws has an elastic arm formed and coupled between the main body and the clamping portion.

14. The clip for clamping an electronic device according to claim 13, wherein the clip is bendable at a connecting position of the elastic arm and the main body.

15. A clip for clamping an electronic device, comprising:
a plurality of main bodies; and
a plurality of claws, each having both ends being coupled to each of the main bodies respectively, and a clamping portion formed on the claw for abutting and coupling the electronic device, and the clamping portions being arranged on at least two different planes.

16. The clip for clamping an electronic device according to claim 15, wherein each of the claws is bent to form the clamping portion.

17. The clip for clamping an electronic device according to claim 15, wherein the claw has an elastic arm formed separately at both ends of the claw, and the clamping portion is disposed between two elastic arms.

18. The clip for clamping an electronic device according to claim 15, wherein each of the main bodies has a through hole formed thereon.

19. The clip for clamping an electronic device according to claim 15, wherein the main body has a positioning pin extended from the main body and bent to a position substantially perpendicular to the main body.

20. The clip for clamping an electronic device according to claim 19, wherein the positioning pin and the claws are coupled to two opposite sides of the main body respectively.
